(19) United States
(12) Patent Application Publication
(10) Pub. No.: US 2023/0044537 A1
(43) Pub. Date: Feb. 9, 2023

(54) RESISTIVE RANDOM ACCESS MEMORY ARRAY AND OPERATION METHOD THEREFOR, AND RESISTIVE RANDOM ACCESS MEMORY CIRCUIT

(71) Applicant: TSINGHUA UNIVERSITY, Beijing (CN)

(72) Inventors: Liyang PAN, Beijing (CN); Jingyao SUN, Beijing (CN); Huaqiang WU, Beijing (CN)

(73) Assignee: TSINGHUA UNIVERSITY, Beijing (CN)

(21) Appl. No.: 17/790,369

(22) PCT Filed: Dec. 30, 2020
(86) PCT No.: PCT/CN2020/141478

§ 371 Date: Jun. 30, 2022

(30) Foreign Application Priority Data
Dec. 31, 2019 (CN) 201911409161.5

(51) Int. Cl. G11C 13/00

(52) U.S. Cl. CPC G11C 13/0028; G11C 13/0026; G11C 13/004

(57) ABSTRACT

A resistive random access memory array and an operation method therefor, and a resistive random access memory circuit. The resistive random access memory array includes multiple memory cells, multiple bit lines, multiple word lines, multiple block selection circuits, and multiple initialization circuits. Each memory cell includes a resistive random access memory device and a switching device. The multiple memory cells are arranged into multiple memory cell rows and multiple memory cell columns in a first direction and a second direction, and the multiple bit lines and the multiple memory cell columns are connected in one-to-one correspondence. Each block selection circuit is configured to write a read/write operation voltage into a correspondingly connected bit line in response to a block selection voltage. Each initialization circuit is configured to write an initialization operation voltage to a correspondingly connected bit line in response to an initialization control voltage.

The present application claims priority of Chinese Patent Application No. 201911409161.5, filed on Dec. 31, 2019, the disclosure of which is incorporated herein by reference in its entirety as part of the present application.

### TECHNICAL FIELD

Embodiments of the present disclosure relate to a resistive random access memory array and an operation method thereof, and a resistive random access memory circuit.

### BACKGROUND

A resistive random access memory (RRAM) is a memory that realizes conversion between high and low resistance values through a resistive variable thin film dielectric material which can change in electrical conductivity under an applied electric field. RRAM has a variety of advantages such as simple structure, high working speed, low power consumption, stable information retention, and non-volatility, and therefore has promising development and application prospects.

### SUMMARY

At least an embodiment of the present disclosure provides a resistive random access memory array comprising a plurality of memory cells, a plurality of bit lines, a plurality of word lines, a plurality of block selection circuits and a plurality of initialization circuits. The plurality of memory cells are arranged into a plurality of memory cell rows and a plurality of memory cell columns in a first direction and a second direction, each memory cell comprises a resistive variable device and a switching device; the resistive variable device comprises a first electrode and a second electrode; and the first electrode of the resistive variable device is electrically connected with the switching device. The plurality of bit lines are extended in the second direction and connected to the plurality of memory cell columns in one to one correspondence, and each of the plurality of bit lines is electrically connected to second electrodes of resistive variable devices in a memory cell column corresponding to the each bit line. The plurality of word lines are extended in the first direction and connected to the plurality of memory cell rows in one to one correspondence, and each of the plurality of word lines is electrically connected to switching devices of memory cells in a memory cell row corresponding to the each word line. The plurality of block selection circuits are electrically connected to the plurality of bit lines in one to one correspondence; and the plurality of initialization circuits are electrically connected to the plurality of bit lines in one to one correspondence. Each block selection circuit comprises a control terminal, a first terminal, and a second terminal; the control terminal of the block selection circuit is configured to receive a block selection voltage, the first terminal of the block selection circuit is configured to receive a read/write operation voltage, and the second terminal of the block selection circuit is electrically connected to a bit line that is correspondingly connected to the block selection circuit; and the block selection circuit is configured to write the read/write operation voltage into a bit line which is correspondingly connected with the block selection circuit in response to the block selection voltage. Each initialization circuit comprises a control terminal, a first terminal, and a second terminal; the control terminal of the initialization circuit is configured to receive an initialization control voltage, the first terminal of the initialization circuit is configured to receive an initialization operation voltage, and the second terminal of the initialization circuit is electrically connected to a bit line that is correspondingly connected to the initialization circuit; and the initialization circuit is configured to write the initialization operation voltage into the correspondingly connected bit line in response to the initialization control voltage.

In some examples, each of the plurality of initialization circuits comprises a switching transistor, and a gate electrode, a first electrode and a second electrode of the switching transistor respectively serve as the control terminal, the first terminal and the second terminal of the initialization circuit; and the switching transistor is a P-type transistor.

In some examples, the switching device comprises a control terminal, a first terminal, and a second terminal; the first electrode of the resistive variable device is electrically connected to the first terminal of the switching device; each word line is electrically connected to control terminals of switching devices of the memory cells in a memory cell row corresponding to the each word line; the RRAM array further comprises a plurality of source lines extended in the second direction, the plurality of source lines are electrically connected to the plurality of memory cell columns in one to one correspondence, and each of the plurality of source lines is electrically connected to second terminals of switching devices of memory cells in a memory cell column corresponding to the each source line.

In some examples, the RRAM array further comprises a plurality of global bit lines, and the plurality of global bit lines are extended in the second direction and are electrically connected to the plurality of block selection circuits in one to one correspondence; and each global bit line is electrically connected to the first terminal of a block circuit correspondingly connected to the each global bit line.

In some examples, the RRAM array further comprises an initialization operation line, and the initialization operation line is extended in the first direction and is electrically connected to first terminals of the plurality of initialization circuits to provide the initialization operation voltage.

At least an embodiment of the present disclosure further provides an RRAM circuit, comprising the RRAM array provided by any one of the above embodiments.

In some examples, the RRAM circuit further comprises an initialization control circuit, and the initialization control circuit is configured to be electrically connected to the plurality of initialization circuits to provide the initialization operation voltage and the initialization control voltage.

In some examples, the RRAM circuit further comprises a column selection circuit, and the column selection circuit is configured to be connected to the plurality of block selection circuits to provide the RRAM array with the read/write operation voltage.

In some examples, the RRAM circuit further comprises a programming control circuit and a read control circuit, and the read/write operation voltage comprises a programming operation voltage and a read operation voltage; the programming control circuit is connected to the column selection circuit and configured to provide the programming operation voltage to the RRAM array through the column selection circuit; and the read control circuit is connected to the column selection circuit and configured to provide the read operation voltage to the RRAM array through the column selection circuit.

At least an embodiment of the present disclosure further provides an operation method for operating the RRAM array according to any one of the above embodiments, the operation method comprising: at an initialization operation stage, turning the plurality of block selection circuits off, and applying the initialization operation voltage to memory cells of at least one selected memory cell row through the plurality of initialization circuits and the plurality of bit lines.

At least an embodiment of the present disclosure further provides an operation method of a resistive random access memory (RRAM) array, and the RRAM array comprises a plurality of memory cells, a plurality of bit lines, a plurality of word lines, a plurality of block selection circuits and a plurality of initialization circuits. The plurality of memory cells are arranged into a plurality of memory cell rows and a plurality of memory cell columns in a first direction and a second direction, and each memory cell comprises a resistive variable device and a switching device; the resistive variable device comprises a first electrode and a second electrode; and the first electrode of the resistive variable device is electrically connected to the switching device. The plurality of bit lines extended in the second direction and connected to the plurality of columns, wherein each of the plurality of bit lines is electrically connected to second electrodes of resistive variable devices of memory cells in a memory cell column corresponding to the each bit line. The plurality of word lines extended in the first direction and correspondingly connected to the plurality of rows, wherein each of the plurality of word lines is electrically connected to switching devices of memory cells in a memory cell row corresponding to the each word line. The plurality of block selection circuits electrically connected to the plurality of bit lines in one to one correspondence. The plurality of initialization circuits electrically connected to the plurality of bit lines in one to one correspondence. The operation method comprises: turning the plurality of block selection circuits off, and performing a first initialization operation and a second initialization operation on memory cells in at least one selected memory cell row through the plurality of initialization circuits and the plurality of bit lines, the first initialization operation preceding the second initialization operation; wherein the first initialization operation comprises applying a first initialization operation voltage V_{F}1 to the memory cells in the at least one selected memory cell row through the plurality of initialization circuits and the plurality of bit lines; and the second initialization operation comprises applying a second initialization operation voltage V_{F}2 to the memory cells in the at least one selected memory cell row through the plurality of initialization circuits and the plurality of bit lines.

In some examples, the first initialization operation voltage V_{F}1 is higher than the second initialization operation voltage V_{F}2.

In some examples, each initialization circuit comprises a control terminal, a first terminal, and a second terminal, and the second terminal of each initialization circuit is electrically connected to a bit line that is correspondingly connected to the each initialization circuit; the first initialization operation further comprises applying a first initialization control voltage V_{FC} 1 to control terminals of the plurality of initialization control circuits to turn the plurality of initialization circuits on; and the second initialization operation further comprises applying a second initialization control voltage V_{FC}2 to the plurality of initialization control circuits to turn the plurality of initialization circuits on.

In some examples, each of the plurality of initialization circuits comprises a switching transistor, and a gate electrode, a first electrode and a second electrode of the switching transistor respectively serve as the control terminal, the first terminal and the second terminal of the initialization circuit; the switching transistor is a P-type transistor; the first initialization control voltage V_{FC}1 is lower than the first initialization operation voltage V_{F}1, and the second initialization control voltage V_{F}2 is lower than the second initialization operation voltage V_{FC}2.

In some examples, a difference V_{F}1−V_{FC}1| between the first initialization operation voltage and the first initialization control voltage is smaller than a difference |V_{F}2−V_{FC}2| between the second initialization operation voltage and the second initialization control voltage.

In some examples, the time of the first initialization operation is longer than that of the second initialization operation.

In some examples, the operation method further comprises: performing, after the second initialization operation, a third initialization operation on the memory cells in the at least one selected memory cell row through the plurality of initialization circuits and the plurality of bit lines, wherein the third initialization operation comprises applying a third initialization operation voltage V_{F}3 to the memory cells in the at least one selected memory cell row through the plurality of initialization circuits and the plurality of bit lines.

In some examples, the magnitudes of the first initialization operation voltage V_{F}1, the second initialization operation voltage V_{F}2 and the third initialization operation voltage V_{F}3 decrease successively.

In some examples, operation time of the first initialization operation, the second initialization operation and the third initialization operation decreases successively.

In some examples, each initialization circuit comprises a control terminal, a first terminal, and a second terminal, and the second terminal of each initialization circuit is electrically connected to a bit line that is correspondingly connected to the each initialization circuit; the first initialization operation further comprises applying a first initialization control voltage V_{FC}1 to the control terminals of the plurality of initialization control circuits to turn the plurality of initialization circuits on; the second initialization operation further comprises applying a second initialization control voltage V_{FC}2 to the plurality of initialization control circuits to turn the plurality of initialization circuits on; the third initialization operation further comprises applying a second initialization control voltage V_{FC}2 to the plurality of initialization control circuits to turn the plurality of initialization circuits on; and a difference |V_{F}1−V_{FC}1| between the first initialization operation voltage and the first initialization control voltage, a difference |V_{F}2−V_{FC}2| between the second initialization operation voltage and the second initialization control voltage and a difference |V_{F}3−V_{FC}3| between the third initialization operation voltage and the third initialization control voltage increase successively.

At least an embodiment of the present disclosure further provides a resistive random access memory (RRAM) array, comprising: a plurality of memory cells a plurality of bit lines, a plurality of word lines, a plurality of block selection circuits and a plurality of initialization circuits. The plurality of memory cells arranged into a plurality of memory cell rows and a plurality of memory cell columns in a first direction and a second direction, and each memory cell comprises a resistive variable device and a switching device; the resistive variable device comprises a first electrode and a second electrode; the switching device comprises a control terminal, a first terminal, and a second terminal; and the first electrode of the resistive variable device is electrically connected to the first terminal of the switching device. The plurality of bit lines extended in the second direction and connected to the plurality of memory cell columns in one to one correspondence, and each of the plurality of bit lines is electrically connected to second electrodes of resistive variable devices of memory cells in a memory cell column corresponding to the each bit line. The plurality of word lines extended in the first direction and connected to the plurality of memory cell rows in one to one correspondence, and each of the plurality of word lines is electrically connected to control terminals of switching devices of memory cells in a memory cell row corresponding to the each word line. The plurality of block selection circuits electrically connected to the plurality of bit lines in one to one correspondence, and each block selection circuit comprises a control terminal, a first terminal, and a second terminal; the control terminal of the block selection circuit is configured to receive a first control signal, the first terminal of the block selection circuit is configured to receive a read/write operation voltage, and the second terminal of the block selection circuit is electrically connected to a bit line that is correspondingly connected to the block selection circuit; and the block selection circuit is configured to write the read/write operation voltage in the correspondingly connected bit line in response to the first control signal; the second terminals of the switching devices of the memory cells in each memory cell row are electrically connected to one another.

In some examples, the RRAM array further comprises a plurality of source lines extended in the first direction and correspondingly connected to the plurality of memory cell rows, and second terminals of switching devices of memory cells in each memory cell row are electrically connected to one another through a source line corresponding to the each memory cell row.

In some examples, the RRAM array further comprises a global source line, and the plurality of source lines are all electrically connected to the global source line so that the second terminals of the switching devices of the memory cells in the plurality of memory cell rows are electrically connected to one another.

In some examples, the second terminals of the switching devices of the memory cells in each memory cell row are all grounded.

In some examples, the RRAM array further comprises a plurality of initialization circuits electrically connected to the plurality of bit lines in one to one correspondence, and each initialization circuit comprises a control terminal, a first terminal, and a second terminal; the control terminal of the initialization circuit is configured to receive an initialization control voltage, the first terminal of the initialization circuit is configured to receive an initialization operation voltage, and the second terminal of the initialization circuit is electrically connected to a bit line that is correspondingly connected to the initialization circuit; and the initialization circuit is configured to write the initialization operation voltage in a bit line which is correspondingly connected with the initialization circuit in response to the initialization control voltage.

At least an embodiment of the present disclosure provides an RRAM circuit, comprising the RRAM array provided by any one of the above embodiments.

In some examples, the RRAM further comprises a source line control circuit, the source line control circuit is configured to be electrically connected to the second terminals of switching devices of one or more memory cell rows to provide a source line voltage.

In some examples, the RRAM further comprises a column selection circuit, a programming and erasing control circuit, and a read control circuit, and the read/write operation voltage comprises a programming operation voltage, an erasing operation voltage, and a read operation voltage; the column selection circuit is connected to the plurality of block selection circuits and configured to be connected to the plurality of block selection circuits to provide the RRAM array with the operation voltage; the programming and erasing circuit is connected to the column selection circuit and configured to provide the programming operation voltage and the erasing operation voltage to the RRAM array through the column selection circuit; and the read control circuit is connected to the column selection circuit and configured to provide the read operation voltage to the RRAM array through the column selection circuit.

At least an embodiment of the present disclosure further provides a driving method for driving the RRAM array provided by any one of the above embodiments, the driving method comprising: applying a word line voltage through the plurality of word lines to select one row of memory cells, applying a source line voltage to second terminals of switching devices of the selected one row of memory cells so that the switching devices are switched to transmit the source line voltage to first electrodes of resistive variable devices of the selected one row of memory cells, and applying an operation voltage to a second electrode of a resistive variable device of at least one memory cell in the selected one row of memory cells through at least one of the plurality of bit lines, wherein the operation voltage comprises a read/write operation voltage and an initialization operation voltage.

In some examples, the source line voltage is a grounding voltage.

### BRIEF DESCRIPTION OF THE DRAWINGS

In order to clearly illustrate the technical solutions of the embodiments of the disclosure, the drawings of the embodiments will be briefly described in the following; it is obvious that the described drawings are only related to some embodiments of the disclosure and thus are not limitative to the disclosure.

FIG. 1A is a structural schematic diagram of a resistive variable device;

FIG. 1B is a diagram illustrating a voltage-current characteristic curve of a resistive variable device;

FIG. 2A is a structural schematic diagram of an RRAM cell;

FIG. 2B is a structural schematic diagram of an RRAM array;

FIG. 2C is a structural schematic diagram of an RRAM circuit;

FIG. 3 is a structural schematic diagram of an RRAM array provided by at least one embodiment of the present disclosure;

FIG. 4 is a diagram illustrating a signal waveform in an operation method of an RRAM array provided in at least one embodiment of the present disclosure;

FIG. 5 is a flowchart of an operation method of an RRAM array provided by at least one embodiment of the present disclosure;

FIG. 6 is a structural schematic diagram of an RRAM circuit provided by at least one embodiment of the present disclosure;

FIG. 7A is a structural schematic diagram of another RRAM array provided by at least one embodiment of the present disclosure;

FIG. 7B is a structural schematic diagram of still another RRAM array provided by at least one embodiment of the present disclosure; and

FIG. 8 is a structural schematic diagram of another RRAM circuit provided by at least one embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly. In order to make the following description of the embodiments of the present disclosure clear and concise, the present disclosure omits detailed descriptions of known functions and known components.

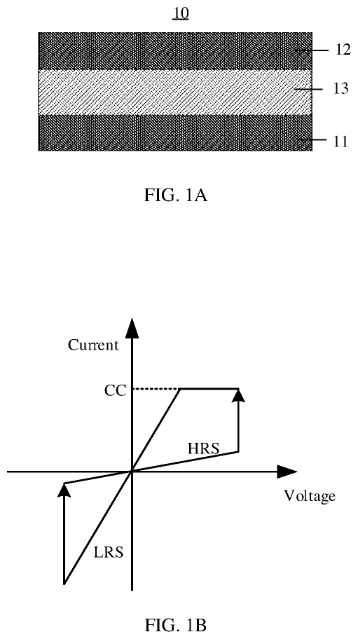

A memory device (also referred to as a resistive variable device or an RRAM device) used by an RRAM device takes the form of, for example, a plate capacitor, including a metal-insulator-metal (MIM) structure. FIG. 1A shows a structural schematic diagram of a resistive variable device, and FIG. 1B shows a current-voltage (I-V) characteristic curve of the resistive variable device.

As shown in FIG. 1A, the resistive variable device 10 includes a first electrode 11, a second electrode 12, and a resistive variable dielectric layer 13 located between the first electrode 11 and the second electrode 12. For example, the first electrode 11 is a bottom electrode of the resistive variable device 10, and the second electrode 12 is a top electrode of the resistive variable device.

For example, the first electrode 11 and the second electrode 12 may include a metal material such as aluminum, silver, copper, platinum, and titanium, or a composite metal material, or include a semiconductor material such as polycrystalline silicon. For example, the resistive variable dielectric layer 13 may include one or more composite dielectric layers. For example, the resistive variable dielectric layer 13 may include a metal oxide material such as hafnium oxide, copper oxide, titanium oxide, and tantalum oxide, or other dielectric material having the resistive variable characteristic.

As shown in FIG. 1B, the I-V characteristic curve of the resistive variable device 10 exhibits hysteresis characteristic. This curve is divided into 4 areas: a high resistance state (HRS) area, a low resistance state (LRS) area, and two transition areas. When a voltage amplitude exceeds a certain threshold, the resistance of the resistive variable device may be caused to change so that rewrite operations (including a programming operation and an erasing operation) can be performed on the resistive variable device 10.

As shown in FIG. 1B, a process in which a forward voltage (V_{Set}) is applied to two terminals of the resistive variable device 10 to cause transition of the resistance from the HRS to the LRS is referred to as a set operation, as known as a write operation or a programming operation. A process in which a backward voltage (V_{RST}) is applied to two terminals of the resistive variable device 10 to cause transition of the resistance from the LRS to the HRS is referred to as a reset operation, as known as an erasing operation. For example, voltage magnitude for realizing the programming operation and the erasing operation is usually between 1.2 V and 3 V. To prevent breakdown of the resistive variable device by a large current generated suddenly during operation, it is necessary to provide a compliance current (CC) to protect the device.

After the completion of manufacturing, the manufactured resistive variable device is usually in the high resistance state, a relatively high initialization operation voltage (e.g., above 3 V) needs to be used to perform an initialization operation on the resistive variable device. After the initialization operation, the resistive variable device can complete the programming operation or the erasing operation under a relatively low voltage. The initialization operation is hereinafter also referred to as a forming operation. For example, an initialization operation of soft breakdown using a higher voltage needs to be added. For example, an initialization operation voltage required by the initialization operation is higher than a voltage required by the set/reset operation, and longer operation time is taken for the former. The initialization operation voltage V_{F} is between 2 V and 6 V.

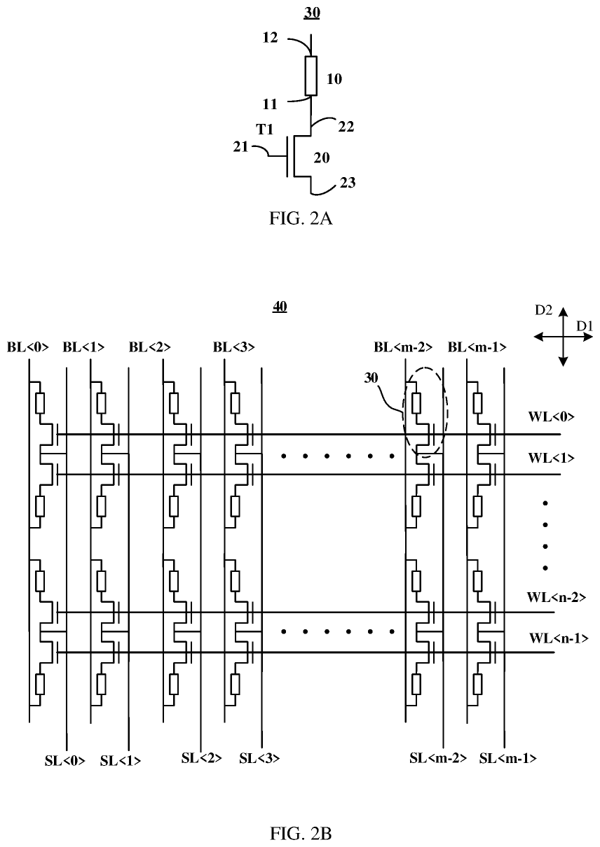

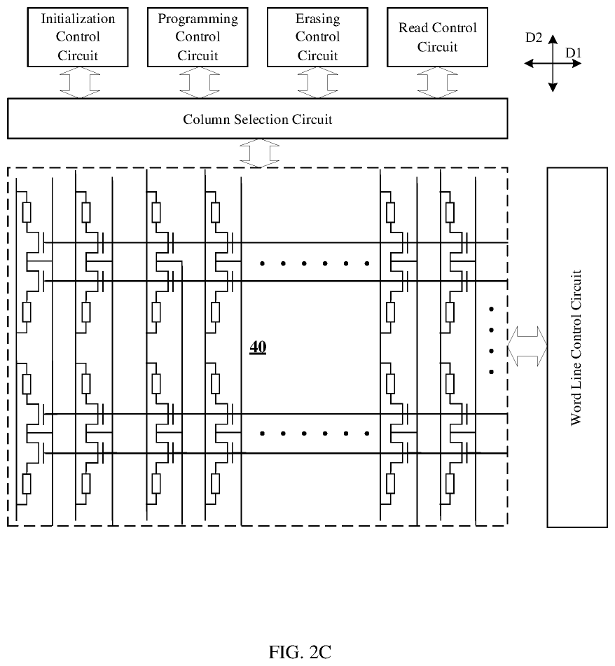

The resistive variable device is typically electrically connected (e.g., connected in series) to a switching device to form a basic memory cell. The switching device may be a two-terminal element (e.g., a diode) or a three-terminal element (e.g., a transistor). FIG. 2A shows a structural schematic diagram of a memory cell. As shown in FIG. 2A, the memory cell 30 includes a resistive variable device 10 and a switching device 20. For example, the switching device 20 is a three-terminal element, including a control terminal 21, a first terminal 22, and a second terminal 23. The first terminal 22 of the switching device 20 is electrically connected to a first electrode 11 of the resistive variable device 10.

For example, the first electrode 11 is a negative electrode of the resistive variable device 10, while a second electrode 12 thereof is a positive electrode of the resistive variable device 10. When a voltage on the first electrode 11 is lower than that on the second electrode 12, the resistive variable device is forward biased. When the voltage on the first electrode 11 is higher than that on the second electrode 12, the resistive variable device is reverse biased. The following embodiments of the present disclosure will be described by taking this for example. However, the embodiments of the present disclosure are not limited thereto. It will be easy for a person skilled in the art to understand that the switching device 20 may also be connected to the second electrode (the positive electrode) of the resistive variable device, and the relationship of magnitude between input signals may be correspondingly adjusted during operation to realize the same function.

For example, the switching device includes a diode or a triode, thereby forming a 1D1R or 1T1R memory cell structure. For example, the switching device includes a first transistor T1, including a metal-oxide-semiconductor field-effect-transistor (MOSFET), thus endowing the 1T1R memory cell with good compatibility with an existing complementary metal-oxide-semiconductor (CMOS) integrated circuit.

A gate electrode, a first electrode and a second electrode of the first transistor T1 serve as the control terminal, the first terminal and the second terminal of the switching device, respectively. When the switching device 20 is switched on, the memory cell 30 is selected to perform the read and write operations and the like of the RRAM device. When the switching device 20 is switched off, the memory cell 30 is not selected.

It needs to be noted that all the transistors used in the embodiments of the present disclosure may be field-effect transistors, thin-film transistors, or other switching devices having the same characteristics. The embodiments of the present disclosure are all described by taking the field-effect transistors for example. The source and the drain of a transistor used herein may be structurally symmetrical and thus may be structurally indistinguishable. In an embodiment of the present disclosure, to distinguish between other two electrodes than the gate electrode of a transistor, one electrode may be directly described as the first electrode, while the other electrode as the second electrode.

A plurality of RRAM cells may be topologically integrated criss-cross into an RRAM array, and a storage apparatus may include one or more such memory arrays.

FIG. 2B shows a structural schematic diagram of an RRAM array. The RRAM array 40 includes an array composed of m columns and n rows (m and n being greater than or equal to 2) of memory cells 30, a plurality of bit lines BL (BL<0> to BL<m−1>), a plurality of word lines WL (WL<0> to WL<n−1>), and a plurality of source lines SL (SL<0> to SL<m−1>). The second electrode 12 of the resistive variable device 10 in each memory cell 30 is connected to one bit line BL, and the control terminal 21 and the second terminal 23 of the switching device 20 in each memory cell 30 are connected to one word line WL and one source line SL, respectively. A desired memory cell 30 may be selected by applying an appropriate voltage to the bit line BL, the word line WL, and the source line SL, so that the initialization (forming), programming (set), erasing (reset) and read operations described above can be performed thereon.

FIG. 2C shows a structural schematic diagram of an RRAM circuit. As shown in FIG. 2C, the RRAM circuit includes one or more RRAM arrays 40 and peripheral circuit. The peripheral circuit include a word line control circuit, a column selection circuit, an initialization control circuit, a programming control circuit, an erasing control circuit, a read control circuit, etc.

The word line control circuit is connected to the word lines WL and for example, applies control voltage signals to the word lines WL in a progressive scanning manner to control the switching devices 20 in one row of memory cells 30 (i.e., the memory cells connected to the same word line WL) in each scanning period, so that the row of memory cells 30 can be selected.

The initialization control circuit generates an initialization operation voltage pulse V_{F} and applies the initialization operation voltage pulse V_{F} to one or more bit lines BL through the column selection circuit to perform the initialization operation on the selected one or more memory cells 30.

The programming control circuit generates a programming operation voltage pulse (V_{Set}) and applies the programming operation voltage pulse through the column selection circuit to one or more bit lines BL to perform the programming operation on the selected one or more memory cells 30.

The erasing control circuit generates an erasing operation voltage pulse (V_{RST}) and applies the erasing operation voltage pulse through the column selection circuit to one or more source lines SL to perform the erasing operation on the selected one or more memory cells 30.

The read control circuit generates a read operation voltage pulse V_{Read} and applies the read operation voltage pulse through the column selection circuit to one or more bit lines BL to perform the read operation on the selected one or more memory cells 30.

For example, the column selection circuit may include an address decoder and may be configured to receive an address signal. The column selection circuit may be controlled by a controller to receive a column address, e.g., a bit line address, of a memory cell to be accessed and decode the received bit line address.

In one aspect, because of a high initialization operation voltage (e.g., above 6 V), the peripheral circuit for providing and transmitting the initialization operation voltage and the RRAM array for receiving the initialization operation voltage need to meet a high voltage withstanding requirement. For example, as shown in FIG. 2C, since the initialization control circuit generates the initialization operation voltage which is transmitted by the column selection circuit to the RRAM array, transistors in the initialization control circuit, the column selection circuit and the RRAM array need to be large in size (e.g., the channel regions of the transistors are great in length and width) to meet the high voltage withstanding requirement, which results in not only increased sizes and manufacturing costs of circuits but also reduced read/write performance of the memory.

In another aspect, due to the differences between the resistive variable devices, different resistive variable devices may take different initialization time to change in resistance and also differ in resistance after the initialization operation. Such a difference in resistance will lead to reduced reliability of the subsequent rewrite operations and an increased error rate of the stored data. To improve the reliability of the subsequent rewrite operations of the resistive variable devices, memory cells having m*n capacity in the RRAM array need to be selected one by one for the initialization operation, and the initialization operation voltage V_{F} and the initialization operation time (pulse time) T_{F} need to be controlled finely so that the resistance of each resistive variable device is within an appropriate range. This needs to take a lot of initialization operation time and leads to an increased test cost.

At least one embodiment of the present disclosure provides an RRAM array including a plurality of block selection circuits and a plurality of initialization circuits, the plurality of block selection circuits are connected to a plurality of bit lines in one to one correspondence and the plurality of initialization circuits are also connected to the plurality of bit lines in one to one correspondence. The block selection circuit is configured to write an operation voltage in the correspondingly connected bit line in response to a block selection voltage. The initialization circuit is configured to write an initialization operation voltage in the correspondingly connected bit line in response to an initialization control voltage.

the RRAM array provided by the above embodiment of the present disclosure, by respectively providing the block selection circuit and the initialization circuit described above, the initialization circuit and the transmission of initialization operation voltage are separated from other control circuits and transmission of operation voltages, so that the transmission of the initialization operation voltage can be achieved not via the column selection circuit described above. For example, during the initialization operation, the block selection circuit may be controlled to be off to avoid the initialization operation voltage applied by the initialization circuit to the bit line from being applied to the column selection circuit. Thus, the voltage withstanding requirement of the column selection circuit may be reduced. Therefore, the RRAM array provided by the embodiment of the present disclosure is helpful to narrow the range of circuits involved with the high initialization operation voltage and reduce the voltage withstanding requirement of the circuits, thus being conducive to reducing the size and the manufacturing cost of the circuit. Moreover, with the initialization circuit, the initialization operation is allowed to be performed simultaneously on a complete row (one or more rows) of memory cells. As a result, time of the initialization operation is significantly shortened, and the efficiency of an initialization test operation is improved with a reduced initialization test cost.

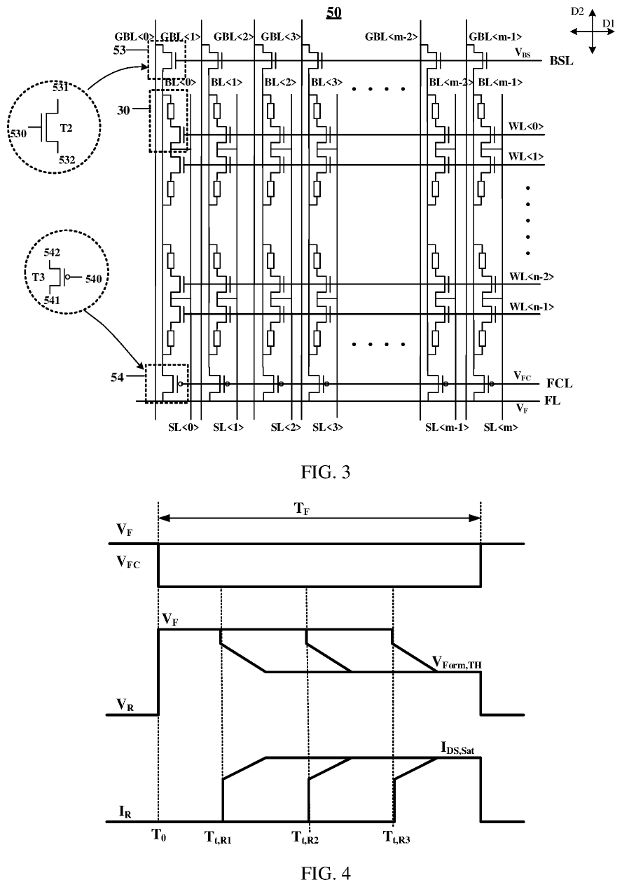

FIG. 3 is a structural schematic diagram of an RRAM array 50 provided by at least one embodiment of the present disclosure. As shown in FIG. 3, the RRAM array 50 includes a plurality of memory cells 30, a plurality of bit lines BL (BL<0> to BL<m−1>), a plurality of word lines WL (WL<0> to WL<n−1>), a plurality of block selection circuits 53, and a plurality of initialization circuits 54. The plurality of memory cells 30 are arranged into n memory cell rows and m memory cell columns (m and n being greater than or equal to 2) in a first direction D1 and a second direction D2. For example, the first direction D1 and the second direction D2 are defined as a row direction and a column direction of the array, respectively.

The plurality of bit lines BL are extended in the second direction D2 and are connected to the plurality of memory cell columns in one to one correspondence. Each of the plurality of bit lines BL is electrically connected to the second electrode 12 of the resistive variable device 10 in each memory cell of the corresponding memory cell column.

The plurality of word lines WL are extended in the first direction D1 and are connected to the plurality of memory cell rows in one to one correspondence. Each of the plurality of word lines WL is electrically connected to the switching device 20 of each memory cell of the corresponding memory cell row. As shown in FIG. 3, each word line WL is electrically connected to the control terminal 21 of the correspondingly connected switching device 20 to provide a word line voltage V_{WL}.

The plurality of block selection circuits 53 are electrically connected to the plurality of bit lines BL in one to one correspondence. For example, the plurality of block selection circuits 53 are arranged in the first direction D1 and located on a first side of the array composed of the plurality of memory cells.

The plurality of initialization circuits 54 are electrically connected to the plurality of bit lines BL in one to one correspondence. For example, the plurality of initialization circuits 54 are arranged in the first direction D1 and located on a second side of the array composed of the plurality of memory cells. The second side and the first side are two opposite sides of the array of the memory cells in the second direction D2.

Each block selection circuit 53 includes a control terminal 530, a first terminal 531, and a second terminal 532. The control terminal 530 of the block selection circuit 53 is configured to receive a block selection voltage V_{BS}, while the first terminal 531 of the block selection circuit 53 is configured to receive a read/write operation voltage, and the second terminal 532 of the block selection circuit 53 is electrically connected to the bit line BL that is correspondingly connected to the block selection circuit 53. The block selection circuit 53 is configured to write the read/write operation voltage in the correspondingly connected bit line BL in response to the block selection voltage V_{BS}. For example, the read/write operation voltage includes the programming operation voltage V_{Set} and the read operation voltage V_{Read} described above.

For example, the block selection circuit 53 includes a second transistor T2. The gate electrode, the first electrode and the second electrode of the second transistor T2 serve as the control terminal 530, the first terminal 531 and the second terminal 532 of the block selection circuit, respectively.

Each initialization circuit 54 includes a control terminal 540, a first terminal 541, and a second terminal 542. The control terminal 540 of the initialization circuit 54 is configured to receive an initialization control voltage V_{FC}, while the first terminal 541 of the initialization circuit 54 is configured to receive an initialization operation voltage V_{F}, and the second terminal 542 of the initialization circuit 54 is electrically connected to the bit line BL that is correspondingly connected to the initialization circuit 54. The initialization circuit is configured to write the initialization operation voltage V_{F} to the correspondingly connected bit line BL in response to the initialization control voltage V_{FC}.

For example, the initialization circuit 54 includes a third transistor T3 (which is an example of a switching transistor in the embodiments of the present disclosure). The gate electrode, the first electrode and the second electrode of the second transistor T3 serve as the control terminal 540, the first terminal 541 and the second terminal 542 of the initialization circuit 54, respectively.

For example, as shown in FIG. 3, the RRAM array 50 further includes a block selection line BSL which is extended in the first direction D1 and connected to the control terminals of the plurality of block selection circuits to provide a block selection voltage V_{BS}.

For example, as shown in FIG. 3, the RRAM array 50 further includes a plurality of global bit lines GBL (GBL<0> to GBL<m−1>) which are extended in the second direction D2 and are electrically connected to the plurality of block selection circuits 53 in one to one correspondence. Each global bit line GBL is electrically connected to the first terminal 531 of the correspondingly connected block selection circuit 53.

At least one embodiment of the present disclosure further provides an RRAM array structure including a plurality of RRAM arrays 50 described above. The plurality of RRAM arrays 50 are arranged, for example, in the first direction D1 and the second direction D2 to form a superior array that also includes a plurality of rows and a plurality of columns. For example, the memory cell columns of the RRAM arrays in the same column in the superior array may be aligned to each another. Likewise, the memory cell rows of the RRAM arrays in the same row may be aligned to each another. For example, the plurality of global bit lines GBL correspond to the same column of memory cells of the plurality of RRAM arrays in the RRAM array structure in one to one correspondence. Each global bit line GBL is correspondingly connected to first terminals 531 of block selection circuits 53 in the same column of the plurality of RRAM arrays in the RRAM array structure. In other words, the first terminals 531 of the plurality of block selection circuits 53 in the same column in the plurality of RRAM arrays are all electrically connected to the corresponding same global bit line GBL.

For example, the block selection voltage V_{BS} may be applied to an RRAM array 50 to be accessed to select the RRAM array 50. Such a block (partition) operation may reduce the circuit load and increase the response speed of the circuit.

For example, as shown in FIG. 3, the RRAM array 50 further includes a plurality of source lines SL (SL<0> to SL<m−1>) which extend in the second direction D2 and are electrically connected to a plurality of memory cell columns in one to one correspondence. Each of the plurality of source lines SL is electrically connected to the second terminals 23 of the switching devices 20 of the memory cells in the corresponding memory cell column.

For example, as shown in FIG. 3, the RRAM array 50 further includes a plurality of initialization operation lines FL and a plurality of initialization control lines FCL. The plurality of initialization operation lines FL and the plurality of initialization control lines FCL extend in the first direction D1. The initialization operation line FL is connected to the first terminal of the initialization circuit 54 to provide the initialization operation voltage V_{F}, and the initialization control line FCL is connected to the control terminal of the initialization circuit 54 to provide the initialization control voltage V_{FC}.

For example, the first transistor T1, the second transistor T2 and the third transistor T3 are N-type transistors or P-type transistors.

For example, in case that the third transistor T3 is a P-type transistor, since the P-type transistor has a threshold voltage of less than 0 and is switched on under the circumstance that a voltage difference Vgs between the gate electrode and the source thereof is less than 0, thus, the initialization control voltage V_{FC} applied to the gate electrode may be lower than the initialization operation voltage V_{F} applied to the first electrode, thereby further reducing the voltage withstanding requirement of the circuit.

An embodiment of the present disclosure further provides an operation method for operating the RRAM array 50 described above. The operation method includes: at an initialization operation stage, turning the plurality of block selection circuits off, and applying, through the plurality of initialization circuits and the plurality of bit lines, an initialization operation voltage to at least one selected row of memory cells to initialize the at least one row of memory cells.

The following description is made on the basis that the first transistor T1 and the second transistor T2 are both N-type transistors while the third transistor T3 is a P-type transistor. However, the embodiments of the present disclosure have no particular limitation on the type of the first to third transistors. When the type of the transistor changes, the relationship of magnitude between signals is correspondingly such that the circuit realizes the same function.

For example, with reference to FIG. 3, at the initialization operation stage, a positive word line voltage V_{WL} is applied through a selected word line WL (e.g., correspondingly connected to one or more rows of memory cells) and a plurality of source lines SL are controlled to be grounded so that the switching devices 20 (the first transistors T1) in the one or more rows of memory cells 30 are switched on, i.e., the one or more rows of memory cells are selected.

For example, at the initialization operation stage, a block selection voltage V_{BS} is applied to the block selection circuit 53 through the block selection line BSL to turn the block selection circuit 53 off. For example, the block selection line BSL is controlled to be grounded so that the second transistor T2 is switched off. Thus, during the initialization operation of the initialization operation stage, the block selection circuit is turned off to isolate the initialization circuits and the transmission of initialization operation voltages from other control circuits and the transmission of operation voltages. Thus, the range of circuits involved with the initialization operation voltages is narrowed, and the voltage withstanding requirement and the size of the circuit are reduced.

For example, the initialization operation voltage V_{F} is applied to the initialization operation line FL and the initialization control voltage V_{FC} is applied to the initialization control line FCL to switch on the third transistor T3. Thus, the initialization circuit is turned on, and the initialization operation voltage V_{F} is transferred to the second electrodes 12 of the resistive variable devices 10 in the at least one selected row of memory cells through the initialization circuit 54 and the plurality of bit lines BL. Meanwhile, the first electrode 11 of the resistive variable device is grounded through the switching device 20 that is turned on and via the corresponding source line SL, thus introducing a forward voltage difference V_{F} between the two terminals of the resistive variable device, which causes soft breakdown to the resistive variable device and converts the resistive variable device from the initial HRS to the LRS. Thus, the initialization operation can be simultaneously performed on the at least one selected row of memory cells.

For example, the third transistor T3 is a P-type transistor, and at the initialization operation stage, the initialization operation voltage V_{F} is applied to the initialization operation line FL and the initialization control voltage V_{FC} is applied to the initialization control line FCL (with the initialization operation voltage V_{F} being higher than the initialization control voltage V_{FC}), so that the third transistor T3 is switched on and the initialization circuit 54 is turned on. For example, the initialization operation voltage V_{F} is between 2 V and 6 V. For example, the pulse time (T_{F}) of the initialization control voltage V_{FC} is in a range of from 1 microsecond to 10 milliseconds.

FIG. 4 is a schematic diagram illustrating a waveform during the simultaneous initialization operation on different memory cells at the initialization operation stage in the operation method provided by the embodiment of the present disclosure.

FIG. 4 schematically illustrates the waveforms of voltage and current of resistive variable devices in three memory cells (R1, R2, R3) in the same row and different columns during the initialization operation. At the beginning of the initialization operation stage, due to extremely high resistance and very small breakover current of the resistive variable device 10 in the selected memory cell, the current flowing through the corresponding third transistor T3 is also very small. In this situation, the third transistor T3 works in a linear area, with a very small voltage difference between the first electrode and the second electrode of the third transistor T3, and the initialization operation voltage V_{F} can be regarded as being fully applied to the resistive variable device 10. As the initialization operation proceeds, at resistance change time (Tₜ), the resistance of the resistive variable device 10 decreases and the breakover current increases, and the current flowing through the corresponding third transistor T3 also increases. When the current increases to the saturated current (I_{DS,Sat}) of the third transistor T3, the third transistor T3 enters a saturation area, with the voltage difference between the first electrode and the second electrode of the third transistor T3 increasing and the breakover current remaining unchanged, and the voltage transferred to the resistive variable device 10 steps down accordingly and finally stops at the minimum critical voltage (V_{Form,TH}) of the initialization operation. The minimum critical voltage is the minimum transition voltage of the resistive variable device. When an external voltage is higher than the minimum critical voltage, the resistance of the resistive variable device decreases. When an external voltage is lower than the minimum critical voltage, the resistance of the resistive variable device remains unchanged. The minimum critical voltage is the inherent nature of the resistive variable device, which is related to, for example, the material, process, structure, etc. of the resistive variable device. After the initialization operation described above, the resistance of the resistive variable device 10 is equal to the ratio V_{Form,TH}/I_{DS,Sat} of the minimum critical voltage to the saturated current.

Thus, the operation method provided by the embodiment of the present disclosure, by introducing the initialization circuits, can limit the voltage applied to the two terminals of the resistive variable device 10 in the selected memory cell and the maximum breakover current, i.e., limit the resistance of the resistive variable device after the initialization operation. Therefore, although a plurality of memory cells in one or more rows that are simultaneously selected for the initialization operation take different time to change resistance due to their differences in structure, material, process, etc., they may eventually reach the same or similar resistance. As a result, the consistency and reliability of the memory cells can be improved significantly. Compared with operating one by one, the time of the initialization operation is greatly shortened.

For example, as shown in FIG. 4, the resistance change time of the memory cells R1, R2, R3 in the same row and different columns increase (delay) successively, but the resistive variable devices 10 eventually reach the same resistance V_{Form,TH}/I_{DS,Sat}. That is, the consistency is achieved.

For example, by the above operation method, the resistance of the resistive variable device after the initialization operation may be defined by defining the saturated current I_{DS,Sat} of the third transistor T3. For example, the initialization operation may have a great influence on the reliability of the subsequent set/reset operation. If the resistance of the resistive variable device after the initialization operation is too high, the reliability of the subsequent set operation will degrade. On the contrary, if the resistance of the resistive variable device after the initialization operation is too low, the reliability of the subsequent reset operation will degrade. Therefore, the above operation method may finely control the resistance of the resistive variable device in a memory cell after the initialization operation so that the resistance of the resistive variable device after the initialization operation is within an appropriate range. Thus, the reliability of the subsequent set/reset rewrite operations is improved. For example, the resistance is between the maximum resistance (corresponding to the HRS) and the minimum resistance (corresponding to the LRS) of the resistive variable device in the write operation after the initialization operation.

Compared with a traditional technique of performing the initialization operation bit by bit, the RRAM array and the operation method thereof provided by the embodiments of the present disclosure may allow for simultaneous initialization operation on a complete row or a plurality of rows of memory cells without sacrificing the consistency and the reliability of the memory cells. As a result, the time of the initialization operation is significantly shortened, and the efficiency of the forming test operation is improved with the reduced initialization test cost.

Moreover, due to the shortened time of the initialization operation, the time for the memory cell being under the stress of the initialization operation voltage is shortened, and therefore, a low-voltage MOSFET having the voltage withstanding requirement of below 3 V may be used to design the switching device of the memory cell. As a result, the area and the manufacturing cost of the memory array can be greatly reduced.

For example, the operation method further includes a programming operation stage and an erasing operation stage. At the programming operation stage, a forward voltage is applied to the resistive variable device in the selected memory cell so that the programming operation is performed on the selected memory cell. At the erasing operation stage, a backward voltage is applied to the resistive variable device in the selected memory cell so that the erasing operation is performed on the selected memory cell. The resistance of the resistive variable device changes from high to low after the programming operation and changes from low to high after the erasing operation.

For example, the selected memory cell is a memory cell on which the programming operation is to be performed at the programming operation stage, for example, one or more memory cells in a row of memory cells.

For example, with reference to FIG. 3, a bit line voltage is applied to the second electrode (the positive electrode) of the resistive variable device of the selected memory cell through the block selection transistor and the bit line, and a source line voltage is applied to the first electrode (the negative electrode) of the resistive variable device of the selected memory cell through the source line and the switching device. The magnitudes of the bit line voltage and the source line voltage are controlled so that the resistive variable device is forward biased or reverse biased, thereby allowing the programming operation or the erasing operation to be performed on the selected memory cell.

For example, to simplify the circuit, the lower one of the bit line voltage and the source line voltage may be defined as a grounding voltage, i.e., the corresponding signal line (bit line or source line) is controlled to be grounded. Correspondingly, the relatively high voltage (programming operation voltage or erasing operation voltage) is designed as a positive voltage.

For example, at the programming operation stage, the bit line voltage is the programming operation voltage. At the erasing operation stage, the source line voltage is the erasing operation voltage.

The operation method provided by the embodiment of the present disclosure is exemplarily described below with reference to FIG. 3.

With reference to FIG. 3, at the programming operation stage, a plurality of initialization circuits are turned off, and block selection circuits are turned on. A positive programming operation voltage V_{Set} is applied to the selected memory cell through at least one block selection circuit 53 and at least one bit line BL, and the source line SL corresponding to the selected memory cell is controlled to be grounded. Thus, a forward voltage is applied to the resistive variable device to perform the programming operation on the memory cell.

For example, the second transistor T2 is of N type. A positive block selection voltage V_{BS} is applied to the block selection line of the selected RRAM array, and a programming operation voltage V_{Set} is applied to at least one global bit line GBL to turn the corresponding at least one block selection circuit on. Besides, the programming operation voltage V_{Set} is transferred to the corresponding bit line BL and applied to the second electrode 12 of the resistive variable device of the selected memory cell.

For example, a word line voltage V_{WL} is applied to the control terminals of the switching devices 20 (the first transistors T1) in a row of memory cells 30 through the selected word line WL (which is correspondingly connected to the selected memory cell), and a source line voltage is applied to the source line SL corresponding to the selected memory cell. For example, the first transistor T1 is an N-type transistor, the word line voltage V_{WL} is a positive voltage, and the source line SL is grounded. Thus, the switching device in the selected memory cell in the row of memory cells is switched on, and the first electrode 11 of the resistive variable device is grounded.

For example, the magnitude of the programming operation voltage V_{Set} is between 1.2 V and 3 V, and the pulse time is between 1 nanosecond and 10 microseconds.

For example, the operation method further includes: at the erasing operation stage, turning a plurality of initialization circuits off and turning block selection circuits on; applying a positive erasing operation voltage V_{RST} to the selected memory cell through the source line SL, and controlling, through at least one block selection circuit 53, the bit line BL corresponding to the selected memory cell to be grounded, thus applying a backward voltage to the resistive variable device to perform the erasing operation on the memory cell.

For example, the second transistor T2 is of N type. A positive block selection voltage V_{BS} is applied to the block selection line of one selected RRAM array, and at least one global bit line GBL is grounded to turn the corresponding at least one block selection circuit on. Besides, the second electrode 12 of the resistive variable device of the selected memory cell is grounded.

For example, a positive word line voltage V_{WL} is applied to the control terminals of the switching devices 20 (the first transistors T1) in a row of memory cells 30 through the selected word line WL (which is correspondingly connected to the selected memory cell), and the erasing operation voltage V_{RST} is applied to at least one source line SL to switch on the switching device of the selected memory cell, so that the erasing operation voltage V_{RST} is transferred to the first electrode 11 of the resistive variable device of the selected memory cell.

For example, the magnitude of the erasing operation voltage V_{RST} is between 1.2 V and 3 V, and the pulse time is between 1 nanosecond and 10 microseconds.

For example, the operation method further includes a read operation stage. For example, at the read operation stage, a plurality of initialization circuits are turned off and at least one block selection circuit (which is correspondingly connected to the selected memory cell) is turned on so that the read operation is performed on the selected memory cell.

For example, the selected memory cell is a memory cell on which the read operation is to be performed.

With reference to FIG. 3, for example, the second transistor T2 is an N-type transistor. A positive block selection voltage V_{BS} is applied to the block selection line of one selected RRAM array, and a read operation voltage V_{Read} is applied to at least one global bit line GBL (which is correspondingly connected to the selected memory cell) to turn the at least one block selection circuit on, so that the read operation voltage V_{Read} is transferred to the second electrode 12 of the resistive variable device of the selected memory cell through the corresponding bit line BL.

For example, a positive word line voltage V_{WL} is applied to the control terminals of the switching devices 20 (the first transistors T1) in a row of memory cells 30 through the selected word line WL (which is correspondingly connected to the selected memory cell), and a plurality of source lines SL are grounded, so that the switching device in the selected memory cell in the row of memory cells is switched on, and the first electrode 11 of the resistive variable device is grounded.

A forward V_{Read} voltage difference is introduced between two electrode terminals of the resistive variable device of the selected memory cell, and a breakover read current (I_{Read}) is generated. The read current is small when the resistance of the resistive variable device is high. The read current is large when the resistance is low. The read operation on the selected memory cell can be completed by detecting the reading current using a peripheral read control circuit.

For example, the read operation voltage V_{Read} is between 0.1 V and 1.2 V, and the pulse time (T_{Set}) is within a range of from 1 nanosecond to 10 microseconds.

At least one embodiment of the present disclosure further provides an operation method for operating the RRAM array 50 described above. The operation method includes performing multiple initialization operations described above on the RRAM array at the initialization operation stage. For example, the number of the initialization operation steps is between 2 and 100 or more. For example, the resistive variable devices and the switching devices of different memory cells may differ in performance due to the differences in structure, material and process between the memory cells. For example, the memory cells differ in minimum critical voltage (V_{Form,TH}), and under the condition of the same voltage, the switching devices differ in saturated current (I_{DS,Sat}). Therefore, the resistive variable devices differ in eventually reached resistance after the initialization operation, and a resistance value distribution occurs.

By the multi-step initialization operation approach, the initialization operation voltage (V_{F}) and the initialization control voltage (V_{FC}) in each initialization operation step may be adjusted successively, allowing the resistance values of the resistive variable devices of a complete row (one or more rows) of operated memory cells to decrease successively and eventually reach desired target values. The resistance values of the resistive variable devices obtained by this approach have better accuracy and consistency.

For example, the resistance value distribution of the resistive variable devices after each initialization operation becomes narrower and a mean value thereof is lower. For example, a standard deviation of the resistance value distribution of a plurality of resistive variable devices after each initialization operation decreases successively, and a weighted mean value of the resistance decreases successively.

For example, for the plurality of steps of initialization operations, the initialization operation voltage V_{F} decreases successively in accordance with an initialization operation time sequence.

By controlling the initialization operation voltage V_{F} to decrease successively, the saturated current increasing effect caused by factors such as short-channel effects of the third transistor T3 may be relieved so that the standard deviation of the resistance value distribution of the resistive variable devices after the initialization operation is reduced. Accordingly, the resistance value distribution becomes narrower and more uniform.

For example, for the plurality of steps of initialization operations, the difference |V_{F}−V_{FC}| between the initialization operation voltage and the initialization control voltage increases successively in accordance with the initialization operation time sequence.

The saturated current of the third transistor T3 is I_{ds,sat}=α(Vgs−Vth)², where a is related to parameters such as the material and the size of the third transistor T3. Since the difference (i.e., Vgs) between the initialization operation voltage and the initialization control voltage determines the magnitude of the saturated current of the third transistor T3, the above setting makes the saturated current I_{ds,sat} in each initialization operation increase successively, thus allowing the mean resistance value (e.g., weighted mean value) of the resistive variable devices of a complete row (one or more rows) of operated memory cells to decrease successively.

For example, for the plurality of steps of initialization operations, the initialization operation time T_{F} decreases successively in accordance with the initialization operation time sequence.

Since the resistance of the resistive variable device decreases gradually as the initialization operation proceeds and the initialization time taken for the resistance to change decreases gradually, the initialization operation time of the plurality of steps of initialization operations may be reduced successively as the initialization operation proceeds, which may save the power consumption of the circuit. For example, the time of the first initialization operation may be the longest.

For example, the operation method includes turning the plurality of block selection circuits off, and performing a first initialization operation and a second initialization operation on at least one selected row of memory cells through the plurality of initialization circuits and the plurality of bit lines. The first initialization operation includes applying a first initialization operation voltage V_{F}1 to the at least one selected row of memory cells through the plurality of initialization circuits and the plurality of bit lines. The second initialization operation includes applying a second initialization operation voltage V_{F}2 to the at least one selected row of memory cells through the plurality of initialization circuits and the plurality of bit lines. The first initialization operation precedes the second initialization operation.

For example, the first initialization operation voltage V_{F}1 is different from the second initialization operation voltage V_{F}2.

For example, with reference to FIG. 3, the first initialization operation voltage and the second initialization operation voltage are both configured to be applied to the second electrodes 12 (the positive electrodes) of the resistive variable devices of the memory cells so that the resistive variable devices are forward biased.

For example, the first initialization operation further includes applying a positive word line voltage V_{WL} through the selected word line WL (which is correspondingly connected to one or more selected rows of memory cells) and controlling a plurality of source lines SL to be grounded so that the switching devices 20 (the first transistors T1) in the one or more selected rows of memory cells are switched on.

For example, the second initialization operation further includes applying a positive word line voltage V_{WL} through the selected word line WL (which is correspondingly connected to one or more selected rows of memory cells) and controlling a plurality of source lines SL to be grounded so that the switching devices 20 (the first transistors T1) in the one or more selected rows of memory cells 30 are switched on.

For example, the first initialization operation further includes applying a first initialization control voltage V_{FC}1 to the control terminals of the plurality of initialization circuits to turn the plurality of initialization circuits on. The second initialization operation further includes applying a second initialization control voltage V_{FC}2 to the plurality of initialization control circuits to turn the plurality of initialization circuits on.

For example, the first initialization control voltage V_{FC}1 is higher than the second initialization control voltage V_{FC}2. By controlling the initialization operation voltage V_{F} to decrease successively, the saturated current increasing effect caused by factors such as short-channel effects of the third transistor T3 may be relieved so that the standard deviation of the resistance value distribution of the resistive variable devices after the initialization operation is reduced. Accordingly, the resistance value distribution becomes narrower and more uniform.

For example, the difference |V_{F}1−V_{FC}1| (the absolute value) between the first initialization operation voltage and the first initialization control voltage is smaller than the difference |V_{F}2−V_{FC}2| (the absolute value) between the second initialization operation voltage and the second initialization control voltage.

The saturated current of the third transistor T3 is I_{ds,sat}=α(Vgs−Vth)², where a is related to parameters such as the material and the size of the third transistor T3. Since the difference (i.e., Vgs) between the initialization operation voltage and the initialization control voltage determines the magnitude of the saturated current of the third transistor T3, the above setting makes the saturated current I_{ds,sat} in each initialization operation increase successively, thus allowing the mean resistance value of the resistive variable devices of a complete row (one or more rows) of operated memory cells to decrease successively.

For example, the time of the first initialization operation is longer than that of the second initialization operation.

In another examples, the difference |V_{F}1−V_{FC}1| (the absolute value) between the first initialization operation voltage and the first initialization control voltage may also be equal to the difference |V_{F}2−V_{FC}2| (the absolute value) between the second initialization operation voltage and the second initialization control voltage.

The embodiments of the present disclosure have no particular limitation on the type of the third transistor T3. The third transistor T3 may be of P type or N type. Appropriate initialization operation voltage and initialization control voltage are selected according to the corresponding transistor type to turn the initialization circuits on. For example, the third transistor T3 is a P-type transistor, the first initialization control voltage V_{FC}1 is lower than the first initialization operation voltage V_{F}1 to turn the plurality of initialization circuits on, and the initialization control voltage V_{F}2 is lower than the second initialization operation voltage V_{FC}2 to turn the plurality of initialization circuits on.

In case that the third transistor T3 is of P type, the initialization control voltage V_{FC} is lower than the initialization operation voltage V_{F}. When a certain initialization operation voltage is selected for performing the initialization operation on the memory cells, the third transistor T3 is designed as P type so that the voltage withstanding requirement of the circuit can be reduced.

For example, the operation method further includes performing, after the second initialization operation, a third initialization operation on at least one selected row of memory cells through the plurality of initialization circuits and the plurality of bit lines. The third initialization operation includes applying a third initialization operation voltage V_{F}3 to the at least one selected row of memory cells through the plurality of initialization circuits and the plurality of bit lines.

For example, the magnitudes of the first initialization operation voltage V_{F}1, the second initialization operation voltage V_{F}2 and the third initialization operation voltage V_{F}3 decrease successively.

For example, the third initialization operation further includes applying a third initialization control voltage V_{FC}3 to the plurality of initialization control circuits to turn the plurality of initialization circuits on.

For example, the magnitudes of the first initialization operation voltage V_{F}1, the second initialization operation voltage V_{F}2, the third initialization operation voltage V_{F}3, the first initialization control voltage V_{FC}1, the second initialization control voltage V_{FC}2 and the third initialization control voltage V_{FC}3 are all between 2 V and 6 V.

For example, the operation times of the first initialization operation, the second initialization operation and the third initialization operation decrease successively.

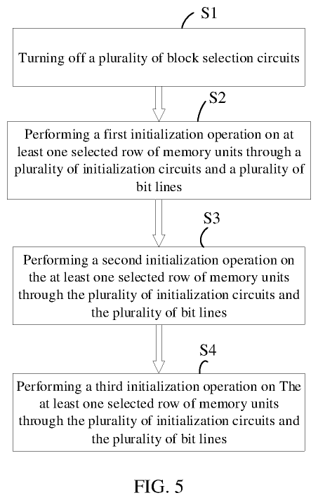

FIG. 5 shows a flowchart of an operation method of an RRAM array provided by at least one embodiment of the present disclosure. FIG. 5 illustrates an example of performing three initialization operations. However, the embodiments of the present disclosure have no particular limitation on the number of the initialization operation steps.

With reference to FIG. 3 and FIG. 5, the operation method includes steps S1 to S4.

Step S1: turning off a plurality of block selection circuits.

For example, a block selection voltage V_{BS} is applied through the block selection line BSL to the block selection circuits 53 to turn the block selection circuits 53 off. For example, the second transistor T2 is an N-type transistor, and the block selection line BSL is grounded, i.e., the block selection voltage V_{BS} is 0.

The block selection circuit is turned off to isolate the initialization circuits and the transmission of the initialization operation voltages from other control circuits and the transmission of the operation voltages. Thus, the range of circuits involved with the initialization operation voltages is narrowed, and the voltage withstanding requirement and the size of the circuit are reduced.

For example, the first transistor T1 is an N-type transistor. A word line voltage V_{WL} is applied through the selected word line WL (which is correspondingly connected to one or more selected rows of memory cells) and a plurality of source lines SL are grounded so that the switching devices 20 (the first transistors T1) in the one or more rows of memory cells 30 are switched on, i.e., the one or more rows of memory cells are selected. The first electrode 21 of the switching device 20 is grounded.

Step S2: performing a first initialization operation on at least one selected row of memory cells through a plurality of initialization circuits and a plurality of bit lines.

For example, the first initialization operation includes applying a first initialization operation voltage V_{F}1 to the initialization operation line FL and a second initialization control voltage V_{FC}2 to the initialization control line FCL, respectively, so that the initialization circuits are turned on and the first initialization operation voltage V_{F}1 is transferred to the second electrodes 22 of the switching devices. The resistive variable device 20 has a forward voltage difference V_{F}1 present between two terminals thereof, and the resistance thereof decreases from an initial value to a first resistance value.

For example, the third transistor T3 is a P-type transistor, and at the initialization operation stage, the first initialization operation voltage V_{F} is higher than the first initialization control voltage V_{FC} so that the third transistor T3 is switched on and the initialization circuit 54 is turned on. For example, the first initialization operation voltage V_{F}1 is between 2 V and 6 V. For example, the pulse time (T_{F}) of the first initialization control voltage V_{FC}1 is within a range of from 1 microsecond to 10 milliseconds.

For example, the plurality of resistive variable devices have a first resistance value distribution and a first mean resistance value (e.g., weighted mean value) after the first initialization operation. The standard deviation of the first resistance value distribution is reduced as compared with that of an initial resistance value distribution, and the first mean resistance value is reduced as compared with an initial mean resistance value.

Step S3: performing a second initialization operation on the at least one selected row of memory cells through the plurality of initialization circuits and the plurality of bit lines.

For example, the second initialization operation includes applying an initialization operation voltage V_{F}2 to the initialization operation line FL and an initialization control voltage V_{FC}2 to the initialization control line FCL, respectively, so that the initialization circuits are turned on and the initialization operation voltage V_{F}2 is transferred to the second electrodes 22 of the switching devices. The resistive variable device 20 has a forward voltage difference V_{F}2 present between two terminals thereof, and the resistance thereof decreases from a first resistance value to a second resistance value.

For example, the third transistor T3 is a P-type transistor, and at the initialization operation stage, the second initialization operation voltage V_{F}2 is higher than the second initialization control voltage V_{FC}2 so that the third transistor T3 is switched on and the initialization circuit 54 is turned on. For example, the second initialization operation voltage V_{F}2 is between 2 V and 6 V. For example, the pulse time of the second initialization control voltage V_{FC}2 is within a range of from 1 microsecond to 10 milliseconds.

For example, the plurality of resistive variable devices have a second resistance value distribution and a second mean resistance value (e.g., weighted mean value) after the second initialization operation. The standard deviation of the second resistance value distribution is less than that of the first resistance value distribution, i.e., the resistance value distribution is more convergent after the second initialization operation. For example, the second mean resistance value is less than the first mean resistance value.

Step S4: performing a third initialization operation on the at least one selected row of memory cells through the plurality of initialization circuits and the plurality of bit lines.

For example, the third initialization operation includes applying an initialization operation voltage V_{F}3 to the initialization operation line FL and an initialization control voltage V_{FC}3 to the initialization control line FCL, respectively, so that the initialization circuits are turned on and the initialization operation voltage V_{F}3 is transferred to the second electrodes 22 of the switching devices. The resistive variable device 20 has a forward voltage difference V_{F}3 present between two terminals thereof, and the resistance thereof decreases from a second resistance value to a third resistance value.

For example, the third transistor T3 is a P-type transistor, and at the initialization operation stage, the third initialization operation voltage V_{F}3 is higher than the third initialization control voltage V_{FC}3 so that the third transistor T3 is switched on and the initialization circuit 54 is turned on. For example, the third initialization operation voltage V_{F}3 is between 2 V and 6 V. For example, the pulse time of the third initialization control voltage V_{FC}3 is within a range of from 1 microsecond to 10 milliseconds.

For example, the plurality of resistive variable devices have a third resistance value distribution and a third mean resistance value (e.g., weighted mean value) after the third initialization operation. The standard deviation of the third resistance value distribution is less than that of the second resistance value distribution, i.e., the resistance value distribution is more convergent after the third initialization operation. The third mean resistance value is less than the second mean resistance value.

For example, the magnitudes of the first initialization operation voltage V_{F}1, the second initialization operation voltage V_{F}2 and the third initialization operation voltage V_{F}3 decrease successively.

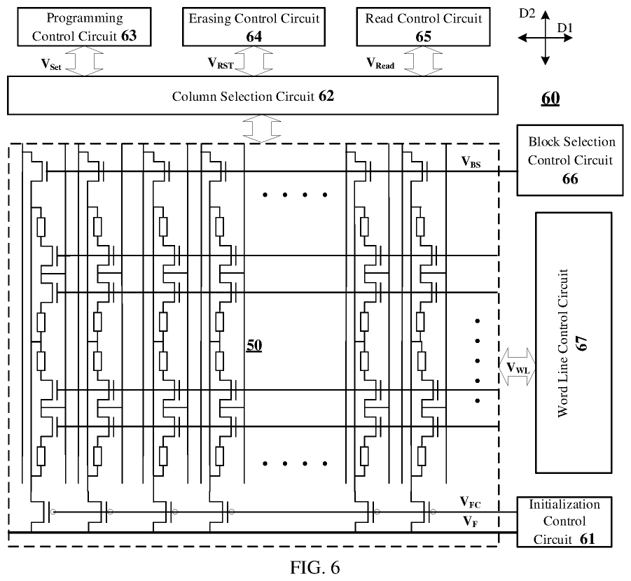

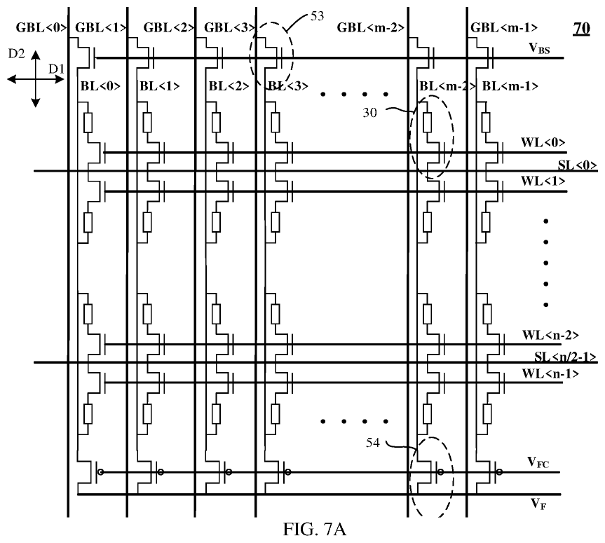

At least one embodiment of the present disclosure further provides an RRAM circuit that includes the RRAM array 50 described above. FIG. 6 is a structural schematic diagram of an RRAM circuit 60 provided by at least one embodiment of the present disclosure.

For example, the RRAM circuit 60 further includes an initialization control circuit 61. The initialization control circuit 61 is configured to be electrically connected to the plurality of initialization circuits 54 to provide the initialization operation voltage V_{F} and the initialization control voltage V_{FC}.

For example, as shown in FIG. 6, the RRAM circuit 60 further includes a column selection circuit 62. The column selection circuit 62 is configured to provide the read/write operation voltage to the RRAM array 50. For example, the read/write operation voltage includes a programming operation voltage V_{Set}, an erasing operation voltage V_{RST}, and a read operation voltage V_{Read}.

For example, the programming operation voltage V_{Set} and the read operation voltage V_{Read} are provided to the RRAM array through a bit line BL, and the erasing operation voltage V_{RST} is provided to the RRAM array through a source line SL, which, however, is not limited in the embodiments of the present disclosure. In another examples, for example, the programming operation voltage V_{Set}, the erasing operation voltage V_{RST} and the read operation voltage V_{Read} may all be provided to the RRAM array through a bit line BL.

For example, the column selection circuit 62 is electrically connected to a plurality of global bit lines GBL.

For example, as shown in FIG. 6, the RRAM circuit 60 further includes a programming control circuit 63, an erasing control circuit 64, and a read control circuit 65.

For example, the programming control circuit 63 is connected to the column selection circuit 62 and configured to provide the programming operation voltage V_{Set} to the RRAM array 50 through the column selection circuit 62. For example, at the programming operation stage, the programming control circuit 63 applies the programming operation voltage V_{Set} to the selected memory cell through the column selection circuit 62 and at least one bit line BL. Thus, a forward voltage is applied to the resistive variable device to perform the programming operation on the memory cell.

For example, the erasing control circuit 64 is connected to the column selection circuit 62 and configured to provide the erasing operation voltage V_{RST} to the RRAM array 50 through the column selection circuit 62. For example, at the erasing operation stage, the erasing control circuit 64 applies the erasing operation voltage V_{RST} to the selected memory cell through the column selection circuit 62 and at least one source line SL, thus applying a backward voltage to the resistive variable device to perform the erasing operation on the memory cell.

For example, the read control circuit 65 is connected to the column selection circuit 62 and configured to provide the read operation voltage V_{Read} to the RRAM array 50 through the column selection circuit 62. For example, at the read operation stage, the read control circuit 65 applies the read operation voltage V_{Read} to the selected memory cell through the column selection circuit 62 and at least one bit line BL. Thus, a forward voltage is applied to the resistive variable device to perform the read operation.

For example, as shown in FIG. 6, the RRAM circuit 60 further includes a block selection control circuit 66 and a word line control circuit 67.

For example, the block selection control circuit 66 is configured to be connected to the block selection line BSL to provide the RRAM array 50 with the block selection voltage V_{BS}.

For example, the word line control circuit 67 is configured to provide the word line voltage V_{WL} to the RRAM array 50. For example, the word line control circuit 67 is electrically connected to a plurality of word lines WL.

More details can be known with reference to the descriptions of the foregoing embodiments regarding the operation method, which are not redundantly described here.

An embodiment of the present disclosure further provides an RRAM array in which the second terminals of switching devices of memory cells in each memory cell row are electrically connected to each another.

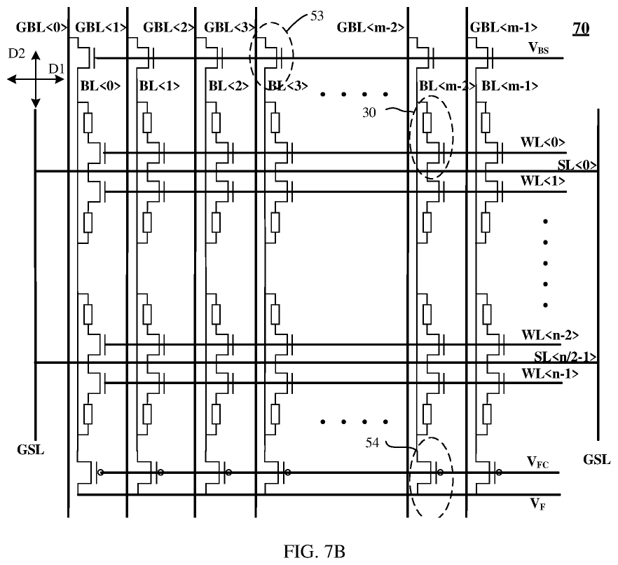

FIG. 7A is a schematic diagram of an RRAM array 70 provided by at least another embodiment of the present disclosure. As shown in FIG. 7A, the RRAM array 70 includes a plurality of memory cells 30, a plurality of bit lines BL, a plurality of word lines WL, and a plurality of block selection circuits 53.

The plurality of memory cells 30 are arranged into n memory cell rows and m memory cell columns (m and n being greater than or equal to 2) in a first direction D1 and a second direction D2. Each memory cell 30 includes a resistive variable device 10 and a switching device 20. The resistive variable device 10 includes a first electrode 11 and a second electrode 12, and the switching device 20 includes a control terminal 21, a first terminal 22, and a second terminal 23. The first electrode 11 of the resistive variable device 10 is electrically connected to the first terminal 22 of the switching device 20. The second terminals 23 of the switching devices 20 of the memory cells 30 in each memory cell row in the first direction D1 are electrically connected to one another.

The plurality of bit lines BL are extended in the second direction D2 and are connected to a plurality of columns of memory cells 30 in one to one correspondence, and each of the plurality of bit lines BL is electrically connected to the second electrodes 12 of the resistive variable devices 10 in the corresponding column of memory cells 30.

The plurality of word lines WL are extended in the first direction D1 and are connected to a plurality of rows of memory cells 30 in one to one correspondence, and each of the plurality of word lines WL is electrically connected to the control terminals 21 of the switching devices 20 of the memory cells in the corresponding row of memory cells 30.

The plurality of block selection circuits 53 are electrically connected to the plurality of bit lines BL in one to one correspondence. Each block selection circuit 53 includes a control terminal 530, a first terminal 531, and a second terminal 532. The control terminal 530 of the block selection circuit 53 is configured to receive a block selection voltage V_{BS}, while the first terminal 531 of the block selection circuit 53 is configured to receive a read/write operation voltage, and the second terminal 532 of the block selection circuit 53 is electrically connected to the bit line BL that is correspondingly connected to the block selection circuit 53. The block selection circuit is configured to write the read/write operation voltage in the correspondingly connected bit line BL in response to the block selection voltage V_{BS}. For example, the read/write operation voltage includes a programming operation voltage V_{Set}, an erasing operation voltage V_{RST}, and a read operation voltage V_{Read}.

As shown in FIG. 7A, the second terminals 23 of the switching devices 20 in each row of memory cells 30 in the first direction D1 are directly electrically connected to one another at a same potential without providing in the second direction D2 a source line that is configured to select the potential of the second terminal 23 of each switching device in a row of memory cells. This is helpful to reduce the wiring density in the second direction, simplify the manufacturing process and increase the yield.

For example, as shown in FIG. 7A, the RRAM array may further include a plurality of source lines SL (SL<0> to SL<n/2−1>) which extend in the first direction D1, i.e., parallel to the plurality of word lines WL. The plurality of source lines SL are correspondingly connected to a plurality of memory cell rows, and the second terminals of the witching devices of the memory cells of each memory cell row are electrically connected to one another through the corresponding source line SL.

For example, the plurality of source lines SL are connected to the plurality of memory cell rows in one to one correspondence. The second terminals 23 of the switching devices 20 of the memory cells 30 of each memory cell row are electrically connected to the corresponding source line SL and electrically connected to one another through this source line SL.

For example, the source lines SL may be insulated from one another or electrically connected to one another, which may not be limited in the embodiments of the present disclosure.

For example, as shown in FIG. 7A, every two adjacent rows of memory cells share one source line SL. The second terminals of the switching devices of every two adjacent rows of memory cells are electrically connected to the same source line SL. Thus, the wiring density can be reduced and the manufacturing cost can be reduced.

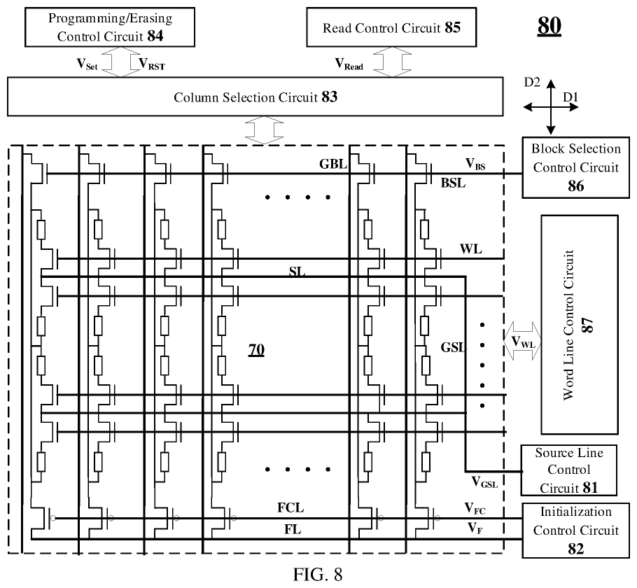

For example, as shown in FIG. 7B, the RRAM array 60 further includes a global source line GSL. The second terminals of the switching devices in each memory cell row are all electrically connected to the global source line GSL. That is, the global source line electrically connects the second terminals of a plurality of switching devices in the RRAM array 60 to one another. The global source line GSL is configured to connect the seconds terminals of the plurality of switching devices to a peripheral circuit (e.g., a source line control circuit shown in FIG. 8) to provide the plurality of memory cells with a source line voltage. The global source line GSL may also be directly grounded.

For example, as shown in FIG. 7B, the global source line GSL extends in the second direction D2.

For example, as shown in FIG. 7B, the number of the global source lines GSL is two. The two global source lines GSL are located on two opposite sides of the RRAM array composed of a plurality of memory cells 30 in the first direction D1, respectively.

For example, the plurality of source lines SL are all electrically connected to the two global source lines GSL on two sides.

For example, the second terminals 23 of a plurality of switching devices 20 in the same memory cell row are connected to the peripheral global source lines GSL through the corresponding source line SL.

For example, the global source lines GSL are grounded so that the second terminals 23 of the switching devices 20 in a plurality of memory cells 30 are grounded.

For example, as shown in FIG. 7A and FIG. 7B, the RRAM array 70 further includes a plurality of initialization circuits 54 that are electrically connected to the plurality of bit lines in one to one correspondence. Each initialization circuit includes a control terminal, a first terminal, and a second terminal. The control terminal of the initialization circuit is configured to receive an initialization control voltage, while the first terminal of the initialization circuit is configured to receive an initialization operation voltage, and the second terminal of the initialization circuit is electrically connected to the bit line that is correspondingly connected to the initialization circuit. The initialization circuit is configured to write the initialization operation voltage in the correspondingly connected bit line in response to the initialization control voltage.

The RRAM array 70 provided in this embodiment differs from the RRAM array 50 in the foregoing embodiment described with reference to FIG. 3 mainly in the arrangement of the source line. Other structures may be known with reference to the description of the foregoing embodiment regarding the RRAM array 50, which will not be redundantly described here.

An embodiment of the present disclosure further provides an operation method for operating the RRAM array 70 described above. The operation method includes: applying a word line voltage through the plurality of word lines to select a row of memory cells, applying a source line voltage to the second terminals of the switching devices of the selected row of memory cells so that the switching devices are switched on and the source line voltage is transferred to the first electrodes of the resistive variable devices of the selected row of memory cells, and applying a read/write operation voltage or an initialization operation voltage to the second electrode of at least one resistive variable device in the selected row of memory cells through at least one of the plurality of bit lines. The read/write operation voltage includes at least one of a programming operation voltage, an erasing operation voltage and a read operation voltage.

Since the second terminals 23 of the switching devices 20 of each row of memory cells are connected to one another at the same potential, when various operations such as the initialization operation, the programming operation, the erasing operation and the read operation are performed with the potential of the first electrode 11, directly connected to the switching device 20, of the resistive variable device as a reference potential, the corresponding initialization operation voltage, programming operation voltage, erasing operation voltage and read operation voltage may be applied to the second electrode 12 of the resistive variable device 10 of the selected memory cell through the bit lines, respectively.

For example, the source line voltage is a grounding voltage. Thus, a forward voltage may be applied through the bit line to perform the initialization operation, the programming operation and the read operation, and a backward voltage may be applied to perform the erasing operation. This is helpful to reduce the voltage amplitude requirement and hence reduce the voltage withstanding requirement of the circuit.

The operation method provided by the embodiment of the present disclosure is exemplarily described below with reference to FIG. 7B. The operation method, for example, includes an initialization operation stage, a programming operation stage, an erasing operation stage, and a read operation stage. For example, the first transistor T1 and the second transistor T2 are both N-type transistors, and the third transistor T3 is a P-type transistor. However, the embodiments of the present disclosure have no particular limitation on the type of the first to third transistors. When the type of the transistor changes, the relationship of magnitude between signals is correspondingly such that the circuit realizes the same function.

For example, at the initialization operation stage, a word line voltage V_{WL} is applied through the selected word line WL (which is correspondingly connected to one or more selected rows of memory cells) and the global source line GSL is controlled to be grounded so that the switching devices 20 (the first transistors T1) in the one or more selected rows of memory cells 30 are switched on.

For example, a block selection voltage V_{BS} is applied through the block selection line BSL to the block selection circuit 53 to turn the block selection circuit 53 off. For example, the block selection line BSL is controlled to be grounded so that the second transistor T2 is switched off. Thus, during the initialization operation of the initialization operation stage, the block selection circuit is turned off to isolate the initialization circuits and the transmission of initialization operation voltages from other control circuits and the transmission of operation voltages. Thus, the range of circuits involved with the initialization operation voltages is narrowed, and the voltage withstanding requirement and the size of the circuit are reduced.

For example, the initialization operation voltage V_{F} is applied to the initialization operation line FL and the initialization control voltage V_{FC} is applied to the initialization control line FCL so that the third transistor T3 is switched on, thus turning the initialization circuit on.

For example, the third transistor T3 is a P-type transistor, and at the initialization operation stage, the initialization operation voltage V_{F} is applied to the initialization operation line FL and the initialization control voltage V_{FC} is applied to the initialization control line FCL (with the initialization operation voltage V_{F} being higher than the initialization control voltage V_{FC}), so that the third transistor T3 is switched on and the initialization circuit 54 is turned on. For example, the initialization operation voltage V_{F} is between 2 V and 6 V. For example, the pulse time (T_{F}) of the initialization control voltage V_{FC} is within a range of from 1 microsecond to 10 milliseconds.

For example, the initialization operation voltage V_{F} is applied to the second electrodes 12 of the resistive variable devices 10 of the at least one selected row of memory cells through the initialization circuit 54 and a plurality of bit lines BL. The first electrode 11 of the resistive variable device is grounded by means of the on switching device 20, thus giving rise to a voltage difference V_{F} between the two ends of the resistive variable device and leading to transition of the resistive variable device from the initial HRS to the LRS due to soft breakdown thereof. Thus, the initialization operation can be simultaneously performed on the at least one selected row of memory cells.

For example, at the programming operation stage, a plurality of initialization circuits are turned off, and block selection circuits are turned on. A positive programming operation voltage V_{Set} is applied to the selected memory cell through at least one block selection circuit 53 and at least one bit line BL, and the global source line GSL is controlled to be grounded. Thus, a forward voltage is applied to the resistive variable device to perform the programming operation on the memory cell.

For example, a positive block selection voltage V_{BS} is applied to the block selection line of the selected RRAM array, and a programming operation voltage V_{Set} is applied to at least one global bit line GBL to turn the corresponding at least one block selection circuit on. Besides, the programming operation voltage is transferred to the corresponding bit line BL and applied to the second electrode 12 of the resistive variable device of the selected memory cell.

For example, a positive word line voltage V_{WL} is applied to the control terminals of the switching devices 20 (the first transistors T1) in a row of memory cells 30 through the selected word line WL (which is correspondingly connected to the selected memory cell). Thus, the switching device in the selected memory cell in the row of memory cells is switched on, and the first electrode 11 of the resistive variable device is grounded.

For example, the magnitude of the programming operation voltage V_{Set} is between 1.2 V and 3 V, and the pulse time is between 1 nanosecond and 10 microseconds.

For example, at the erasing operation stage, a plurality of initialization circuits are turned off, and block selection circuits are turned on. A positive erasing operation voltage V_{RST} to the selected memory cell through at least one block selection circuit 53 and at least one bit line BL, and the global source line GSL is controlled to be grounded, thus applying a backward voltage to the resistive variable device to perform the erasing operation on the memory cell.

For example, a positive block selection voltage V_{BS} is applied to the block selection line of the selected RRAM array, and an erasing operation voltage V_{RST} is applied to at least one global bit line GBL to turn the corresponding at least one block selection circuit on, so that the negative erasing operation voltage V_{RST} is transferred to the corresponding bit line BL and applied to the second electrode 12 of the resistive variable device of the selected memory cell.

For example, a positive word line voltage V_{WL} is applied to the control terminals of the switching devices 20 in a row of memory cells 30 through the selected word line WL (which is correspondingly connected to the selected memory cell). Thus, the switching device in the selected memory cell in the row of memory cells is switched on, and the first electrode 11 of the resistive variable device is grounded.

For example, the magnitude of the erasing operation voltage V_{RST} is between −1.2 V and −3 V, and the pulse time is between 1 nanosecond and 10 microseconds.

For example, the operation method further includes a read operation stage. For example, at the read operation stage, a plurality of initialization circuits are turned off and at least one block selection circuit (which is correspondingly connected to the selected memory cell) is turned on so that the read operation is performed on the selected memory cell.

For example, with reference to FIG. 7B, a positive block selection voltage V_{BS} is applied to the block selection line of one selected RRAM array, and a read operation voltage V_{Read} is applied to at least one global bit line GBL (which is correspondingly connected to the selected memory cell) to turn the at least one block selection circuit on, so that the read operation voltage V_{Read} is transferred to the second electrode 12 of the resistive variable device of the selected memory cell through the corresponding bit line BL.

For example, a positive word line voltage V_{WL} is applied to the control terminals of the switching devices 20 (the first transistors T1) in a row of memory cells 30 through the selected word line WL (which is correspondingly connected to the selected memory cell), and the global source line GSL is grounded. Thus, the switching device in the selected memory cell in the row of memory cells is switched on, and the first electrode 11 of the resistive variable device is grounded.

A forward V_{Read} voltage difference is introduced between two electrode terminals of the resistive variable device of the selected memory cell, and a breakover read current (I_{Read}) is generated. The read current is small when the resistance of the resistive variable device is high. The read current is large when the resistance is low. The read operation on the selected memory cell can be completed by detecting the reading current using a peripheral read control circuit.

For example, the read operation voltage V_{Read} is between 0.1 V and 1.2 V, and the pulse time is within a range of from 1 nanosecond to 10 microseconds.

For example, the operation method may include a plurality of steps of initialization operations. For example, the operation method provided by the embodiment as shown in FIG. 5 is also applicable to the RRAM array 70, which will not be described redundantly here.

An embodiment of the present disclosure further provides an RRAM circuit 80 that includes the RRAM array 70 described above.

FIG. 8 is a structural schematic diagram of an RRAM circuit 80 provided by at least one embodiment of the present disclosure. As shown in FIG. 8, the RRAM circuit 80 further includes a source line control circuit 81 which is configured to be electrically connected to the second terminals of the switching devices of one or more memory cell rows to provide a source line voltage.

For example, the source line control circuit 81 may be connected to a plurality of source lines SL to provide a plurality of memory cell rows with a source line voltage. The source line voltages received by the memory cell rows may be the same or different.

For example, the source line control circuit 81 may also be electrically connected to the global source line GSL to provide the RRAM array 70 with a source line voltage.

For example, the global source line GSL may be directly grounded, and in this case, the source line control circuit 81 may also be omitted.

For example, the RRAM circuit 80 further includes an initialization control circuit 82 The initialization control circuit 82 is configured to be electrically connected to the plurality of initialization circuits 54 to provide the initialization operation voltage V_{F} and the initialization control voltage V_{FC}.

For example, as shown in FIG. 8. the RRAM circuit 80 further includes a column selection circuit 83. The column selection circuit 83 is configured to be connected to a plurality of block selection circuits 53 to provide the RRAM array 70 with a read/write operation voltage. For example, the read/write operation voltage includes a programming operation voltage V_{Set}, an erasing operation voltage V_{RST}, and a read operation voltage V_{Read}.

For example, the column selection circuit 83 is electrically connected to a plurality of global bit lines GBL.

For example, the RRAM circuit 80 further includes a programming and erasing control circuit 84 and a read control circuit 85.

For example, the programming and erasing control circuit 84 is connected to the column selection circuit 83 and configured to provide the programming operation voltage V_{Set} and the erasing operation voltage V_{RST} to the RRAM array 70 through the column selection circuit 83.

For example, at the programming operation stage, the programming and erasing control circuit 84 applies a positive programming operation voltage V_{Set} to the selected memory cell through the column selection circuit 83 and at least one bit line BL. Thus, a forward voltage is applied to the resistive variable device to perform the programming operation on the memory cell.

For example, at the programming operation stage, the programming and erasing control circuit 84 applies a negative erasing operation voltage V_{RST} to the selected memory cell through the column selection circuit 83 and at least one bit line BL. Thus, a backward voltage is applied to the resistive variable device to perform the erasing operation on the memory cell.

Since the programming operation voltage and the erasing operation voltage are both applied to the memory cell through the bit line, the programming control circuit and the erasing control circuit may be integrated into a single circuit module. For example, the programming and erasing control circuit 84 includes a positive voltage generation circuit and a negative voltage generation circuit to generate a positive programming operation voltage at the programming operation stage and a negative erasing operation voltage at the erasing operation stage, respectively.

For example, the read control circuit 85 is connected to the column selection circuit 83 and configured to provide the read operation voltage V_{Read} to the RRAM array 70 through the column selection circuit 83. For example, at the read operation stage, the read control circuit 85 applies the read operation voltage V_{Read} to the selected memory cell through the column selection circuit 83 and at least one bit line BL. Thus, a forward voltage is applied to the resistive variable device to perform the read operation on the memory cell.

For example, as shown in FIG. 8, the RRAM circuit 80 further includes a block selection control circuit 86 and a word line control circuit 87.

For example, the block selection control circuit 86 is configured to be connected to the block selection line BSL to provide the RRAM array 70 with the block selection voltage V_{BS}.

For example, the word line control circuit 87 is configured to provide the word line voltage V_{WL} to the RRAM array 70. For example, the word line control circuit 87 is electrically connected to a plurality of word lines WL.

More details can be known with reference to the descriptions of the foregoing embodiments regarding the operation method, which will not be redundantly described here.

At least one embodiment of the present disclosure further provides an electronic apparatus including an RRAM circuit of any one embodiment described above. The electronic apparatus may be a storage apparatus, a hard disk, a mobile device, a mobile phone, a notebook computer, a desktop computer, etc.

What have been described above are only specific implementations of the present disclosure, the protection scope of the present disclosure is not limited thereto, and the protection scope of the present disclosure should be based on the protection scope of the claims.

1. A resistive random access memory (RRAM) array, comprising:
a plurality of memory cells arranged into a plurality of memory cell rows and a plurality of memory cell columns in a first direction and a second direction, wherein each of the plurality of memory cell comprises a resistive variable device and a switching device; the resistive variable device comprises a first electrode and a second electrode; and the first electrode of the resistive variable device is electrically connected with the switching device;
a plurality of bit lines extended in the second direction and connected to the plurality of memory cell columns in one to one correspondence, wherein each of the plurality of bit lines is electrically connected to second electrodes of resistive variable devices in a memory cell column corresponding to the each bit line;
a plurality of word lines extended in the first direction and connected to the plurality of memory cell rows in one to one correspondence, wherein each of the plurality of word lines is electrically connected to switching devices of memory cells in a memory cell row corresponding to the each word line;
a plurality of block selection circuits electrically connected to the plurality of bit lines in one to one correspondence; and
a plurality of forming circuits electrically connected to the plurality of bit lines in one to one correspondence,
wherein each of the plurality of block selection circuits comprises a control terminal, a first terminal, and a second terminal; the control terminal of the block selection circuit is configured to receive a block selection voltage, the first terminal of the block selection circuit is configured to receive a read/write operation voltage, and the second terminal of the block selection circuit is electrically connected to a bit line that is correspondingly connected to the block selection circuit; and the block selection circuit is configured to write the read/write operation voltage into a bit line which is correspondingly connected with the block selection circuit in response to the block selection voltage;
each of the plurality of forming circuits comprises a control terminal, a first terminal, and a second terminal; the control terminal of the forming circuit is configured to receive an initialization control voltage, the first terminal of the forming circuit is configured to receive an initialization operation voltage, and the second terminal of the forming circuit is electrically connected to a bit line that is correspondingly connected to the forming circuit; and the forming circuit is configured to write the initialization operation voltage into the correspondingly connected bit line in response to the initialization control voltage.

2. The RRAM array according to claim 1, wherein each of the plurality of forming circuits comprises a switching transistor, and a gate electrode, a first electrode and a second electrode of the switching transistor respectively serve as the control terminal, the first terminal and the second terminal of the forming circuit; and
the switching transistor is a P-type transistor.

3. The RRAM array according to claim 1, wherein the switching device comprises a control terminal, a first terminal, and a second terminal; the first electrode of the resistive variable device is electrically connected to the first terminal of the switching device; each of the plurality of word lines is electrically connected to control terminals of switching devices of the memory cells in a memory cell row corresponding to the each word line;
the RRAM array further comprises a plurality of source lines extended in the second direction, the plurality of source lines are electrically connected to the plurality of memory cell columns in one to one correspondence, and each of the plurality of source lines is electrically connected to second terminals of switching devices of memory cells in a memory cell column corresponding to the each source line.

4. The RRAM array according to claim 1, further comprising a plurality of global bit lines,
wherein the plurality of global bit lines are extended in the second direction and are electrically connected to the plurality of block selection circuits in one to one correspondence; and each global bit line is electrically connected to the first terminal of a block selection circuit correspondingly connected to the each global bit line.

5. The RRAM array according to claim 1, further comprising an initialization operation line,
wherein the initialization operation line is extended in the first direction and is electrically connected to first terminals of the plurality of forming circuits to provide the initialization operation voltage.

6. An RRAM circuit, comprising the RRAM array according to claim 1 and a peripheral circuit connected with the RRAM array.

7. The RRAM circuit according to claim 6, wherein the peripheral circuit comprises an initialization control circuit, and
the initialization control circuit is configured to be electrically connected to the plurality of forming circuits to provide the initialization operation voltage and the initialization control voltage.

8. The RRAM circuit according to claim 6, wherein the peripheral circuit comprises a column selection circuit, and
the column selection circuit is configured to be connected to the plurality of block selection circuits to provide the RRAM array with the read/write operation voltage.

9. The RRAM circuit according to claim 8, wherein the peripheral circuit further comprises a programming control circuit and a read control circuit,
wherein the read/write operation voltage comprises a programming operation voltage and a read operation voltage;
the programming control circuit is connected to the column selection circuit and configured to provide the programming operation voltage to the RRAM array through the column selection circuit; and
the read control circuit is connected to the column selection circuit and configured to provide the read operation voltage to the RRAM array through the column selection circuit.

10. (canceled)

11. The RRAM array according to claim 1,
wherein second terminals of switching devices of the memory cells in each of the plurality of memory cell rows are electrically connected to each another.

12. The RRAM array according to claim 11, further comprising:
a plurality of source lines extended in the first direction and correspondingly connected to the plurality of memory cell rows in one to one correspondence,
wherein the second terminals of the switching devices of memory cells in each memory cell row are electrically connected to each another through a source line corresponding to the each memory cell row.

13. The RRAM array according to claim 12, further comprising a global source line,
wherein the plurality of source lines are all electrically connected to the global source line so that second terminals of switching devices of memory cells in the plurality of memory cell rows are electrically connected to each another.

14. The RRAM array according to claim 11, wherein the second terminals of the switching devices of the memory cells in each memory cell row are all grounded.

15. The RRAM circuit according to claim 6, wherein the peripheral circuit comprises a source line control circuit, and
the source line control circuit is configured to be electrically connected to second terminals of switching devices of one or more memory cell rows to provide a source line voltage.

16. An operation method for operating the RRAM array according to claim 1, the operation method comprising:
at an initialization operation stage, turning the plurality of block selection circuits off, and applying the initialization operation voltage to memory cells of at least one selected memory cell row through the plurality of forming circuits and the plurality of bit lines.

17. The operation method according to claim 16, wherein applying the initialization operation voltage to the memory cells of the at least one selected memory cell row through the plurality of forming circuits and the plurality of bit lines comprises:
performing a first initialization operation and a second initialization operation on memory cells in at least one selected memory cell row through the plurality of forming circuits and the plurality of bit lines, the first initialization operation preceding the second initialization operation,
wherein the first initialization operation comprises applying a first initialization operation voltage V_{F}1 to the memory cells in the at least one selected memory cell row through the plurality of forming circuits and the plurality of bit lines; and
the second initialization operation comprises applying a second initialization operation voltage V_{F}2 to the memory cells in the at least one selected memory cell row through the plurality of forming circuits and the plurality of bit lines.

18. The operation method according to claim 17, wherein the first initialization operation voltage V_{F}1 is higher than the second initialization operation voltage V_{F}2.

19. The operation method according to claim 17, wherein the first initialization operation further comprises applying a first initialization control voltage V_{FC} 1 to control terminals of the plurality of initialization control circuits to turn the plurality of forming circuits on; and
the second initialization operation further comprises applying a second initialization control voltage V_{FC}2 to the plurality of forming circuits to turn the plurality of forming circuits on.

20. The operation method according to claim 19, wherein each of the plurality of forming circuits comprises a switching transistor, and a gate electrode, a first electrode and a second electrode of the switching transistor respectively serve as the control terminal, the first terminal and the second terminal of the forming circuit; the switching transistor is a P-type transistor;
the first initialization control voltage V_{FC}1 is lower than the first initialization operation voltage V_{F}1, and the second initialization control voltage V_{F}2 is lower than the second initialization operation voltage V_{FC}2.

21. The operation method according to claim 19, wherein a difference |V_{F}1−V_{FC}1| between the first initialization operation voltage and the first initialization control voltage is smaller than a difference |V_{F}2−V_{FC}2| between the second initialization operation voltage and the second initialization control voltage.

22. The operation method according to claim 17, wherein the time of the first initialization operation is longer than that of the second initialization operation.

23. The operation method according to claim 17, wherein applying the initialization operation voltage to the memory cells of the at least one selected memory cell row through the plurality of forming circuits and the plurality of bit lines further comprises:
performing, after the second initialization operation, a third initialization operation on the memory cells in the at least one selected memory cell row through the plurality of forming circuits and the plurality of bit lines,
wherein the third initialization operation comprises applying a third initialization operation voltage V_{F}3 to the memory cells in the at least one selected memory cell row through the plurality of forming circuits and the plurality of bit lines.

24. The operation method according to claim 23, wherein the magnitudes of the first initialization operation voltage V_{F}1, the second initialization operation voltage V_{F}2 and the third initialization operation voltage V_{F}3 decrease successively.

25. The operation method according to claim 23, wherein operation time of the first initialization operation, the second initialization operation and the third initialization operation decreases successively.

26. The operation method according to claim 23, wherein the first initialization operation further comprises applying a first initialization control voltage V_{FC}1 to the control terminals of the plurality of initialization control circuits to turn the plurality of forming circuits on;
the second initialization operation further comprises applying a second initialization control voltage V_{FC}2 to the plurality of forming circuits to turn the plurality of forming circuits on;
the third initialization operation further comprises applying a third initialization control voltage V_{FC}3 to the plurality of forming circuits to turn the plurality of forming circuits on; and
a difference |V_{F}1−V_{FC}1| between the first initialization operation voltage and the first initialization control voltage, a difference |V_{F}2−V_{FC}2| between the second initialization operation voltage and the second initialization control voltage and a difference |V_{F}3−V_{FC}3| between the third initialization operation voltage and the third initialization control voltage increase successively.
